(19) United States
(12) Patent Application Publication
(10) Pub. No.: US 2004/0262035 A1
(43) Pub. Date: Dec. 30, 2004

(54) Electronic component mounting structure

(76) Inventors: Bing-Hong Ko, Miao-Li (TW); Mao-Yuan Huang, Miao-Li (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/883,244

(22) Filed: Jun. 30, 2004

(30) Foreign Application Priority Data
Jun. 30, 2003 (TW) 92212048

(51) Int. Cl. H05K 1/09; H05K 7/06

(52) U.S. Cl. 174/260; 257/778; 257/737

(57) ABSTRACT

An electronic component mounting structure (2) with reinforced mechanical connecting performance includes a packaging substrate (23) and an electronic chip (21) mounted thereon. A plurality of pairs of conductive bumps (211) and conductive pads (231) respectively formed on the electronic chip and the packaging substrate are mechanically and electrically connected together. In addition, mechanical connection between the packaging substrate and the electronic chip is enhanced by mechanical connection between a plurality of pairs of dummy bumps (212) and dummy pads (232) respectively formed on corners of the electronic chip and the packaging substrate. An anisotropic conductive film (ACF) (22) is sandwiched between the packaging substrate and the electronic chip, and bonds the packaging substrate and the electronic chip together.

### BACKGROUND OF THE INVENTION

1. Field of the Invention

The invention generally relates to electronic component mounting structures and associated liquid crystal display (LCD) devices.

2. The Prior Art

In general, a monochrome or color LCD device has the advantages of thinness, low weight, and low power consumption. For this reason, LCDs are widely used in various types of electronic equipment, from pocket calculators to large-scale office automation equipment.

Conventionally, an LCD device includes a liquid crystal display panel and a backlight device. The liquid crystal display panel includes two parallel, transparent glass substrates, and a liquid crystal layer sealed in a chamber formed by the two glass substrates. A plurality of thin-film transistors (TFTs) is arranged in a matrix on an inner surface of one of the glass substrates. A plurality of wires extends from the TFTs, and is laid on the inner surface. In addition, electronic devices (such as driver ICs; i.e., driver integrated circuits) are attached to a packaging portion of the liquid crystal display panel via adhesive material, and electrically connect with ends of the wires for driving the liquid crystal display panel. The combined electronic devices (or just one electronic device), packaging portion and adhesive material is defined herein as an electronic component mounting structure.

Referring to FIG. 5, a conventional electronic component mounting structure 1 is shown. The electronic component mounting structure 1 includes a packaging glass substrate 13 of a liquid crystal display panel (not shown), a driver IC 11, and an anisotropic conductive film (ACF) 12 sandwiched therebetween and adhering the glass substrate 13 and the driver IC 11 together. The driver IC 11 includes an IC body (not labeled), and a plurality of conductive bumps 111 disposed on a surface of the IC body. The glass substrate 13 forms a plurality of conductive pads 131 thereon, corresponding to the conductive bumps 111. The conductive pads 131 are electrically connected to TFTs (not shown) of the liquid crystal display panel.

The ACF 12 contains a plurality of conductive balls 122 dispersed therethroughout. The ACF 12 has the function of mechanically joining the driver IC 11 and the glass substrate 13 together. Moreover, the ACF 12 electrically interconnects the conductive bumps 111 of the driver IC 11 to the respective conductive pads 131 of the glass substrate 13 by mechanical electrode connection, while providing insulation between adjacent pairs of conductive bumps 111 and conductive pads 131.

With reference to FIG. 6, the driver IC 11 is bonded to the glass substrate 13 using heat. Under specific temperature, speed and pressure conditions, a pre-pressing and a main-pressing processes are performed to form a mechanical joint between the driver IC 11 and the glass substrate 13 via the ACF 12. In this state, pressure and heat are applied on a side of the driver IC 11 that has no conductive bumps 11, whereby the adhesive 40 becomes softened. The conductive balls 122 dispersed in the ACF 12 are pressed between the conductive bumps 111 and the conductive pads 131, such that the conductive balls 122 collectively establish a plurality of electrical interconnections between the conductive pads 131 and the conductive bumps 111. Subsequently, the softened ACF 12 is hardened so that the driver IC 11 is securely bonded on the glass substrate 13. As a final step, measures are taken to release stresses created during the bonding process. The driver IC 11 is thus bonded to the glass substrate 13.

The electronic component mounting structure 1 overcomes many of the problems associated with other similar prior art, by directly attaching the driver IC 11 to the glass substrate 13. This can decrease the space occupied by the LCD, so that the finished device is suitable for more miniaturized applications. However, the electronic component mounting structure 1 has the following problems. Because the driver IC 11 and the packaging glass substrate 13 are both rigid and because their commonly jointed area is relatively large, residual stress stored in the electronic component mounting structure 1 tends to be dispersed to four corners of the driver IC 11. The driver IC 11 is thus liable to warp relative to the glass substrate 13. The conductive bumps 111 may mechanically and electrically detach from the corresponding conductive pads 131, thereby causing circuits of the electronic component mounting structure 1 to fail.

In addition, the electronic component mounting structure 1 may be subjected to shock or vibration during use. The driver IC 11 is liable to detach from the glass substrate 13, especially at the four corners of the driver IC 11, leading to the same kind of circuit failure as described above.

Another conventional electronic component mounting structure is provided in U.S. Pat. No. 5,872,393. In this patent, “[a]t least one of the electrode and the interconnecting conductive film may be provided with a dummy pad for reducing impact load which does not contribute to signal transmission or power supply” (column 5, lines 64 to 67), and “the dummy pads for reducing impact load are disposed on the periphery of the semiconductor chip” (column 6, lines 12 to 13). The patent also discloses that “[t]he present embodiment is characterized by four dummy pads 4a to 4d provided at four corners of the semiconductor chip 207 and unconnected to any of the terminals of the bipolar transistor 5” (column 20, lines 7 to 10). Since the dummy pads 4a to 4d are unconnected to any of the terminals of the bipolar transistor 5, the electronic component mounting structure cannot provide additional mechanical connection between the semiconductor chip 207 and the corresponding packaging substrate, and the semiconductor chip 207 is liable to distort (i.e., warp upwardly) at its corners.

Therefore, a new electronic component mounting structure with reinforced mechanical performance is desired.

### SUMMARY OF THE INVENTION

An object of the present invention is to provide an electronic component mounting structure with enhanced mechanical performance.

An electronic component mounting structure in accordance with the present invention comprises a packaging substrate and an electronic chip mounted thereon. A plurality of pairs of conductive bumps and conductive pads respectively formed on the electronic chip and the packaging substrate are mechanically and electrically connected together. In addition, mechanical connection between the packaging substrate and the electronic chip is enhanced by mechanical connection between a plurality of pairs of dummy bumps and dummy pads respectively formed on corners of the electronic chip and the packaging substrate. An ACF is sandwiched between the packaging substrate and the electronic chip, and bonds the packaging substrate and the electronic chip together.

Other objects, advantages, and novel features of the present invention will become more apparent from the following detailed description when taken in conjunction with the accompanying drawings, in which:

### BRIEF DESCRIPTION OF THE DRAWINGS

FIG. 1 is a schematic, cross-sectional view of a precursor structure of an electronic component mounting structure in accordance with a preferred embodiment of the present invention, showing the precursor structure before a bonding process is applied thereto;

FIG. 2 is a simplified, bottom elevation of a driver IC of the precursor electronic component mounting structure of FIG. 1, showing distribution of a plurality of conductive bumps and dummy bumps thereof;

FIG. 3 is similar to FIG. 1, but showing the electronic component mounting structure of the present invention duly formed after the precursor electronic component mounting structure of FIG. 1 has had the bonding process applied thereto;

FIG. 4 is similar to FIG. 3, but showing the electronic component mounting structure slightly deformed at opposite sides thereof;

FIG. 5 is a schematic, cross-sectional view of a conventional electronic component mounting structure; and

FIG. 6 is similar to FIG. 5, but showing a precursor structure of the conventional electronic component mounting structure thereof, the precursor structure being ready to have a bonding process applied thereto.

### DESCRIPTION OF THE PREFERRED EMBODIMENT

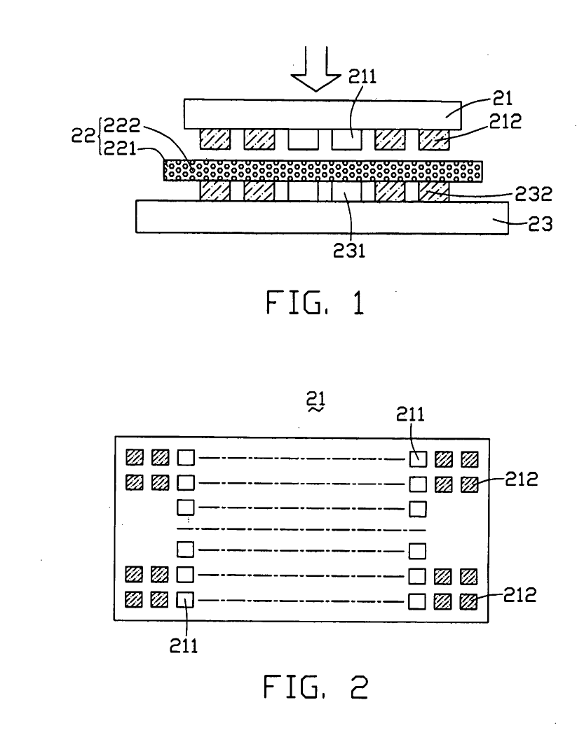

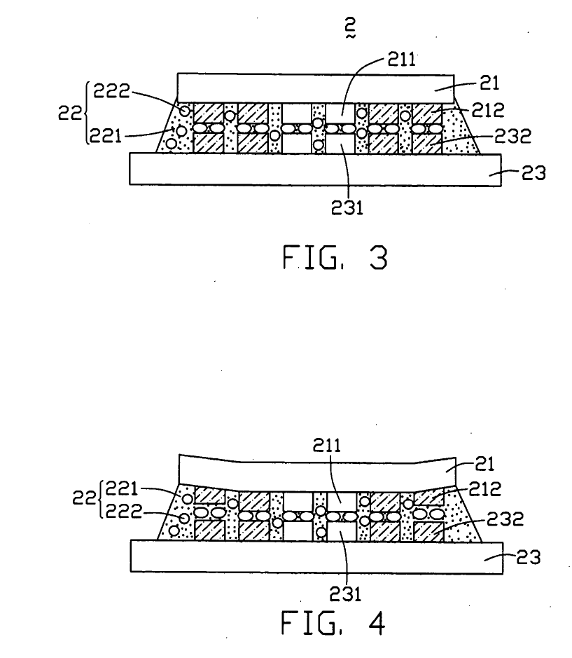

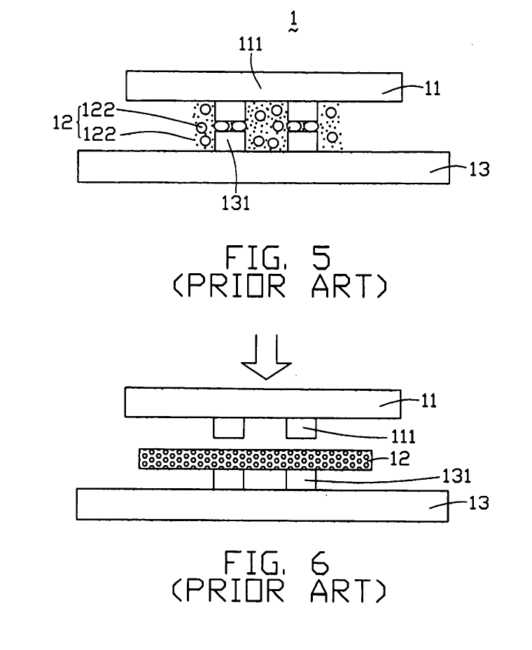

FIGS. 1 and 3 show two states of an electronic component mounting structure of the present invention, respectively before and after a bonding process is applied thereto.

In total, the electronic component mounting structure 2 in accordance with the present invention includes a glass substrate 23 of a liquid crystal display panel (not shown), a driver IC 21, and an ACF 22 sandwiched therebetween and adhering the above two elements together. The driver IC 21 includes a strip-like, quadrate IC body (not labeled), a plurality of conductive bumps 211 regularly disposed on a bottom surface of the IC body, and a plurality of dummy bumps 212 also disposed on the bottom surface of the IC body (see below). The ACF 22 is made of an electrically insulative adhesive material 221 having a plurality of conductive balls 222 dispersed therein. In alternative embodiments, the conductive balls 222 may instead be conductive masses having another shape. A length of the ACF 22 is greater than a corresponding overall length spanned by dummy pads 232 of the glass substrate 23 (see below), and greater than a corresponding overall length spanned by the dummy bumps 212 of the driver IC 21. An original state of the ACF 22 is shown in FIG. 1, before the bonding process is performed.

Referring also to FIG. 2, the conductive bumps 211 are preferably square, and may alternatively be rectangular or circular. The conductive bumps 211 are made of gold material or an alloy of tin and lead, and connect with an internal circuit of the driver IC 21. The dummy bumps 212 are preferably square, and may alternatively be rectangular or circular. The dummy bumps 212 are made of gold material or an alloy of tin and lead, and are mechanically joined to the same surface of the IC body whereat the conductive bumps 211 are formed. However, the dummy bumps 212 do not electrically connect with the internal circuit of the driver IC 21. The dummy bumps 212 are located at a periphery of the array of conductive bumps 211. Preferably, the dummy bumps 212 are disposed at two opposite lengthwise ends of the driver IC 21. More preferably, the dummy bumps 212 are disposed at four corners of said surface of the IC body.

A plurality of conductive pads 231 and the dummy pads 232 are disposed on a surface of the glass substrate 23 facing the driver IC 21. In particular, the conductive pads 231 are regularly disposed on the surface of glass substrate 23 corresponding to respective conductive bumps 211 of the driver IC 21, and electrically connect with active matrix elements formed on the liquid crystal display panel. The dummy pads 232 are regularly disposed on the surface of glass substrate 23 corresponding to respective dummy bumps 212 of the driver IC 21. The dummy pads 232 are mechanically joined to the surface of the glass substrate 23, but do not electrically connect with the active matrix elements of the liquid crystal display panel.

When the bonding process is performed, the driver IC 21 is bonded to the glass substrate 23 using heat. The bonding forms a mechanical and electrical connection between the driver IC 21 and the glass substrate 23 via the ACF 22. In particular, under specific temperature, speed and pressure conditions, a pre-pressing and a main-pressing process are performed. Pressure and heat are applied on the opposite sides of the driver IC 21 where there are no conductive bumps 211, and the adhesive material 221 of the ACF 22 becomes molten and then hardens.

During the above processes, because the driver IC 21 is pressed on the glass substrate 23, the ACF 22 is compressed so that the conductive bumps 211 closely approach the corresponding conductive pads 231. Some conductive balls 222 between the conductive bumps 211 and the conductive pads 231 are thus deformably pressed so that they each abuttingly contact both the conductive bumps 211 and the conductive pads 231. Therefore, the conductive balls 222 collectively establish a plurality of electrical interconnections between the conductive pads 231 and the conductive bumps 211. This plurality of conductive paths also has insulation between adjacent conductive paths, which is provided by the adhesive material 221. Similarly, the dummy bumps 212 and the corresponding dummy pads 232 are mechanically joined together, but with no electrically conductive paths established therebetween.

As a final step, suitable measures are taken to release stresses that may have been created in the bonding process, as is well known in the art. Thus the driver IC 21 is securely and reliably bonded to the glass substrate 23.

Referring to FIG. 3, as a result of the bonding process, a firm electronic component mounting structure 2 is obtained. The active matrix elements of the liquid crystal display panel can be controlled by the driver IC 21, via the electronic component mounting structure 2 and wires disposed on the glass substrate 23.

Referring to FIG. 4, after the bonding process, residual stress may still exist in corners of the driver IC 21 of the electronic component mounting structure 2. Further, in use, the driver IC 21 may be subjected to shock or vibration. Any of these vicissitudes may result in warpage of the driver IC 21, and consequential disconnection of outermost of the dummy bumps 212 from the corresponding dummy pads 232. However, even when this occurs, electrical interconnections between the conductive bumps 211 and the corresponding conductive pads 231 inside the electronic component mounting structure 2 are not disturbed. Good electrical and mechanical performance of the electronic component mounting structure 2 can be maintained for a long time.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. An electronic component mounting structure comprising:
a packaging substrate having a plurality of conductive pads, and a plurality of dummy pads disposed at a periphery of the conductive pads; and
an electronic device mounted on the packaging substrate, having a plurality of conductive bumps and dummy bumps being respectively mechanically connected with the conductive pads and dummy pads.

2. The electronic component mounting structure as claimed in claim 1, wherein the dummy pads and the corresponding dummy bumps are disposed at corners of a surface of the electronic device.

3. The electronic component mounting structure as claimed in claim 1, wherein the conductive bumps and the dummy bumps of the electronic device are square, rectangular or circular.

4. The electronic component mounting structure as claimed in claim 1, wherein the electronic device is joined to the packaging substrate via an anisotropic conductive film.

5. The electronic component mounting structure as claimed in claim 1, wherein the conductive bumps and the dummy bumps of the electronic device are made of gold material.

6. The electronic component mounting structure as claimed in claim 1, wherein the conductive bumps and the dummy bumps of the electronic device are made of an alloy of tin and lead.

7. An electronic component mounting structure comprising: a packaging substrate and an electronic chip mounted thereon; a plurality of electrically connective paths formed between the packaging substrate and the electronic chip; and mechanical connection enhancement means at a periphery of the electrically connective paths, for enhancing stability and durability of the electrically connective paths.

8. The electronic component mounting structure as claimed in claim 7, wherein the mechanical connection enhancement means comprises dummy pads on the substrate and corresponding dummy bumps on the electronic chip.

9. The electronic component mounting structure as claimed in claim 8, wherein the dummy pads and dummy bumps are disposed at corners of a surface of the electronic chip.

10. The electronic component mounting structure as claimed in claim 8, wherein the electrically connective paths comprise conductive bumps on the electronic chip.

11. The electronic component mounting structure as claimed in claim 9, wherein the conductive bumps and the dummy bumps of the electronic chip are square, rectangular or circular.

12. The electronic component mounting structure as claimed in claim 7, wherein the electronic device is joined to the packaging substrate via an anisotropic conductive film.

13. The electronic component mounting structure as claimed in claim 9, wherein the conductive bumps and the dummy bumps of the electronic chip are made of gold material.

14. The electronic component mounting structure as claimed in claim 9, wherein the conductive bumps and the dummy bumps of the electronic chip are made of an alloy of tin and lead.

15. An electronic component mounting structure comprising:
a packaging substrate with a plurality of conductive pads and a plurality of dummy pads thereon; and
an electronic device mounted upon the packaging substrate and having a plurality of conductive bumps in alignment with the corresponding conductive pads, respectively, and a plurality of dummy bumps in alignment with the corresponding dummy pads, respectively, wherein
a deformable conductive film is sandwiched between the packaging substrate and the electronic device to mechanically engage not only pairs of the conductive pads and bumps but also pairs of dummy pads and bumps, while only electrically engaging the pairs of the conductive pads and bumps.
